(19) United States
(12) Patent Application Publication
(10) Pub. No.: US 2005/0196897 A1
(43) Pub. Date: Sep. 8, 2005

(54) Method and apparatus for joining semiconductor

(75) Inventor: Toru Kuboi, Hino-shi (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, TOKYO (JP)

(21) Appl. No.: 11/070,116

(22) Filed: Mar. 2, 2005

(30) Foreign Application Priority Data
Mar. 4, 2004 (JP) 2004-060768

(51) Int. Cl. H01L 21/44

(52) U.S. Cl. 438/106

(57) ABSTRACT

In a method of joining a semiconductor, a semiconductor chip and a substrate are joined together so that spacers and a joining material are interposed between the semiconductor chip and the substrate. The method includes controlling a gap between the semiconductor chip and the substrate during joining on the basis of information on curing and shrinkage of the joining material. The information on the curing and shrinkage of the joining material is information stored in a predetermined storage section and relating to the amount of displacement of the gap between the semiconductor chip and the substrate, this displacement being associated with the curing and shrinkage of the joining material.

### CROSS-REFERENCE TO RELATED APPLICATIONS

This application is based upon and claims the benefit of priority from prior Japanese Patent Application No. 2004-060768, filed Mar. 4, 2004, the entire contents of which are incorporated herein by reference.

### BACKGROUND OF THE INVENTION

1. Field of the Invention

The present invention relates to a method and apparatus for joining a semiconductor, and in particular, to a method and apparatus for joining a semiconductor in which a semiconductor chip and a substrate are joined together via spacers and a joining material.

2. Description of the Related Art

In recent years, an optical function, for example, a lens or a mirror, has been added to a semiconductor chip or substrate mounted in an optical product such as an optical communication device or a microscope. A large number of optical products have been developed in this manner in order to reduce the number of parts used in, and the sizes of, the products, and to improve product functions. For many of these products, to allow the product to function effectively, the semiconductor and the substrate must be joined together with a predetermined distance positively maintained between them. In this case, the gap between the semiconductor chip and the substrate is desirably more accurate than that used in conventional junctions.

However, with the prior art, the main requirements for the junction between the semiconductor chip and the substrate are that a high mechanical junction intensity is ensured and that electrical conduction is obtained. It is not often necessary that a gap is accurately controlled between the semiconductor chip and the substrate. Consequently, there are few joining apparatuses or methods having a function for accurately controlling the gap between the semiconductor chip and the substrate.

Jpn. Pat. Appln. KOKAI Publication No. 2000-252324 proposes a technique relating to a device in which the gap between the semiconductor chip and the substrate is positively controlled as well as a method for manufacturing such a device. This conventional technique will be described with reference to FIG. 7. According to the conventional technique, a semiconductor package is configured as described below.

Silica spacers 109 (or silicon rubber spacers) are interposed between a semiconductor element 101 and an interposer 111 consisting of a film 102 and an interconnect pattern 103. A bonding paste 106 is cured to join the semiconductor element 101 and the interposer 111 together. Thus, the semiconductor element 101 and the interposer 111 can be joined together so that the gap between the semiconductor element 101 and the interposer 111 has a predetermined amount. In this regard, Jpn. Pat. Appln. KOKAI Publication No. 2000-252324 has the following description. If high-elasticity members such as silicon rubber spacers are used, deformation may occur when the semiconductor element 101 is mounted. Accordingly, it is necessary to avoid exceeding the range of elastic deformation of the silicon rubber spacers. Therefore, joining is desirably carried out while regulating the pressure associated with the mounting so as to maintain a substantial difference between the amount of actual elastic deformation and its threshold.

### BRIEF SUMMARY OF THE INVENTION

According to a first aspect of the present invention, there is provided, a method of joining a semiconductor in which a semiconductor chip and a substrate are joined together so that spacers and a joining material are interposed between the semiconductor chip and the substrate, the method comprising controlling a gap between the semiconductor chip and the substrate during joining on the basis of information on curing and shrinkage of the joining material.

According to a second aspect of the present invention, there is provided, a method of joining a semiconductor, the method comprising: firstly pressing a semiconductor chip held by a tool against a substrate held on a stage with spacers and a joining material interposed between the semiconductor chip and the substrate; firstly curing the joining material interposed between the semiconductor chip and the substrate after the firstly pressing; measuring a displacement amount of the tool when the tool is displaced in a direction of the firstly pressing; storing the measured displacement amount; secondly pressing the semiconductor chip against the substrate with a gap between the semiconductor chip and the substrate offset on the basis of the stored displacement amount when the semiconductor chip is pressed against the substrate with the spacers and the joining material interposed between the semiconductor chip and the substrate after each of the firstly pressing, the firstly curing, the measuring, and the storing has been executed at least once; and secondly curing the joining material interposed between the semiconductor chip and the substrate after the secondly pressing.

According to a third aspect of the present invention, there is provided, a semiconductor joining apparatus which joins a semiconductor chip and a substrate together so that spacers and a joining material are interposed between the semiconductor chip and the substrate, the apparatus comprising a control section which controls a gap between the semiconductor chip and the substrate during joining on the basis of information on curing and shrinkage of the joining material.

According to a fourth aspect of the present invention, there is provided, a semiconductor joining apparatus which joins a semiconductor chip and a substrate together so that spacers and a joining material are interposed between the semiconductor chip and the substrate, the apparatus comprising: a tool which holds the semiconductor chip; a stage which holds the substrate; a pressing section which presses the semiconductor chip against the substrate by adjusting a thrust of the tool; a displacement sensor which measures, when the semiconductor chip is pressed against the substrate, the displacement amount of the tool in a direction of the pressing; a storage section which stores an output value from the displacement sensor; and a control section which controls a position of the tool in the direction of the pressing on the basis of the output value stored in the storage section.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram showing the configuration of a semiconductor joining apparatus according to a first embodiment of the present invention;

FIG. 2 is flowchart showing the first half of a process executed to join parts together according to the first embodiment of the present invention;

FIG. 3 is flowchart showing the second half of the process executed to join parts together according to the first embodiment of the present invention;

FIGS. 4A to 4E are diagrams illustrating curing and shrinkage of a joining material;

FIG. 5 is flowchart showing a process executed to join parts together according to a second embodiment of the present invention;

FIG. 6 is flowchart showing a process executed to join parts together according to a third embodiment of the present invention; and

FIG. 7 is a diagram illustrating the prior art.

### DETAILED DESCRIPTION OF THE INVENTION

Embodiments of the present invention will be described below with reference to the drawings.

### First Embodiment

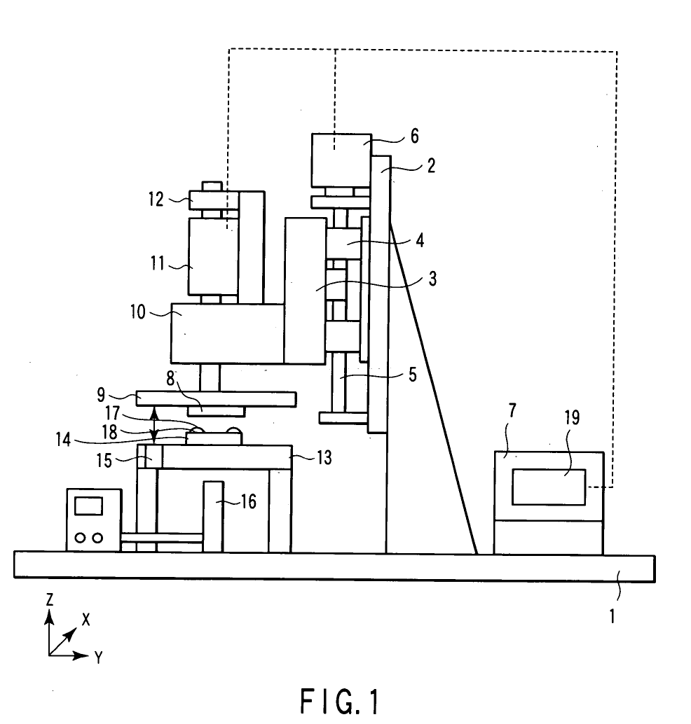

FIG. 1 is a diagram showing the configuration of a semiconductor joining apparatus according to a first embodiment of the present invention. In FIG. 1, an angle plate 2 is installed on a base 1 of the present semiconductor joining apparatus. A Z stage 3 that is movable in the direction of the Z axis (the vertical direction of the figure) is installed on the angle plate 2. In this case, the Z stage 3 is composed of a guide 4, a ball screw 5, and a motor 6. With this configuration, the rotative motion of the motor 6 is converted into linear motion. A guide 4 attached to the ball screw 5 is linearly moved in the direction of the Z axis. Further, a controller 7 serving as a control section is electrically connected to the motor 6. The controller 7 can drive the Z stage 3 to an arbitrary position at an arbitrary speed.

A tool guide 10 is attached to the Z stage 3. A tool 9 that holds a semiconductor chip 8 is supported on the tool guide 10 so as to be slidable in the direction of the Z axis. The tool guide 10 can be pressed by a pressing mechanism 11 that can generate either an arbitrary upward or downward thrust. Furthermore, a lock mechanism 12 to fix the tool 9 is provided on the Z stage 3.

A stage 13 electrically connected to the controller 7 is installed on the base 1. The controller 7 can locate the stage 13 at an arbitrary position in the directions of the X and Y axes.

In this case, the stage 13 can hold a substrate 14 by, for example, adsorbing so that the substrate 14 is opposite a semiconductor chip 8. Moreover, spacers 17 and a joining material 18 are pre-arranged on the substrate 14; the spacers 17 are composed elastic bodies, for example, resin beads, and the joining material 18 consists of, for example, an ultraviolet curing adhesive. A material for the substrate 14 desirably has a high transmittance for ultraviolet rays and is, for example, quartz glass. This is because the joining material is of the ultraviolet curing type.

Further, at least one displacement sensor 15 is installed on the stage 13. The displacement sensor 15 enables the measurement of the distance between the stage 13 and a surface of the tool 9 on which the semiconductor chip 8 is held. The displacement sensor 15 is further electrically connected to the controller 7. The displacement sensor 15 is configured so that its output can be stored in the controller 7. The controller 7 contains a memory 19 serving as a storage section. An output value from the displacement sensor 15, described later, is stored in the memory 19.

At least a part of the stage 13 which contacts with the substrate 14 is manufactured of, for example, quartz glass, which allows ultraviolet rays to pass through. Moreover, a UV irradiation device 16 is installed immediately below a part of the stage 13 on which the substrate 14 is held. The substrate 14 can be irradiated with ultraviolet rays generated by the UV irradiation device 16. Further, the UV irradiation device 16 is electrically connected to the controller 7. This enables the controller 7 to control the activation and stoppage of the UV irradiation device 16 and an irradiation time during operation.

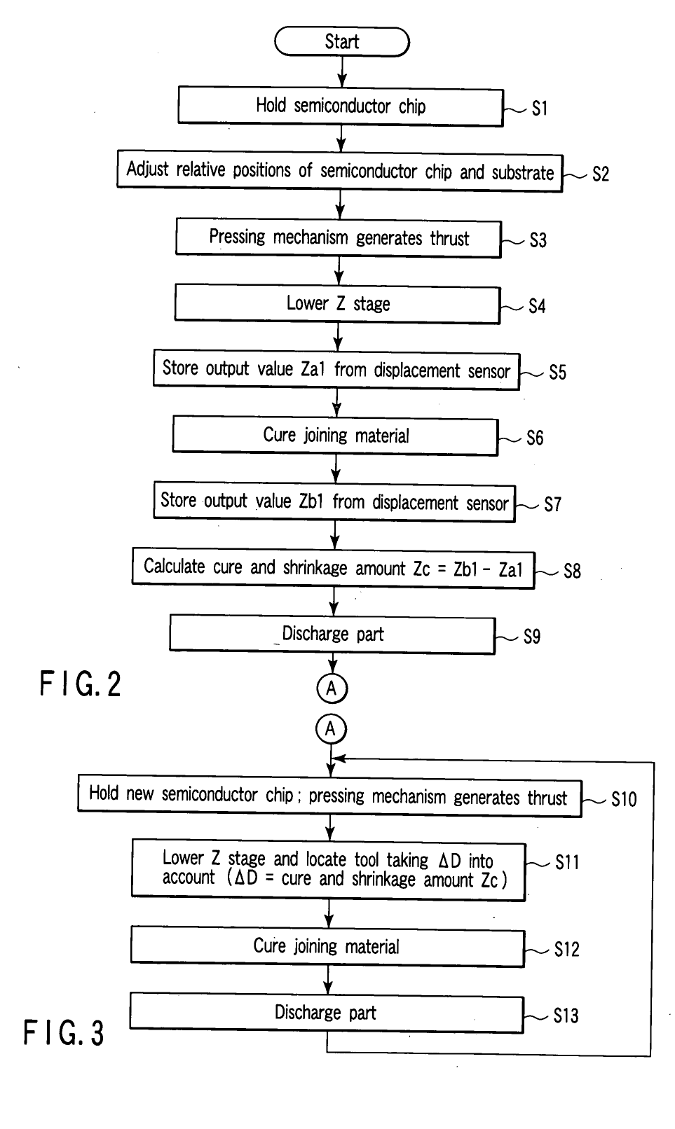

Now, description will be given of a method of joining a semiconductor using a semiconductor joining apparatus such as the one shown in FIG. 1. FIGS. 2 and 3 are flowcharts showing a process executed to join parts together according to the first embodiment of the present invention.

First, an operator or the like uses the lock mechanism 12 to fix the tool 9. The operator then drives the motor 6 to position the Z stage 3 at an arbitrary height. The operator causes a supply section (not shown) to hold the substrate 4 on the stage 13 at a predetermined position so that the substrate 4 faces in a predetermined direction. The operator also causes the tool 9 to hold the semiconductor chip 8 at a predetermined position on the tool 9 so that the semiconductor chip 8 faces in a predetermined direction (step S1).

Then, the stage 13 is driven so that the substrate 14 and the semiconductor chip 8 are located at predetermined relative positions (step S2). The tool 9 is then released from being fixed by the lock mechanism 12. Subsequently, the pressing mechanism 11 is used to generate a predetermined pressing force (step S3).

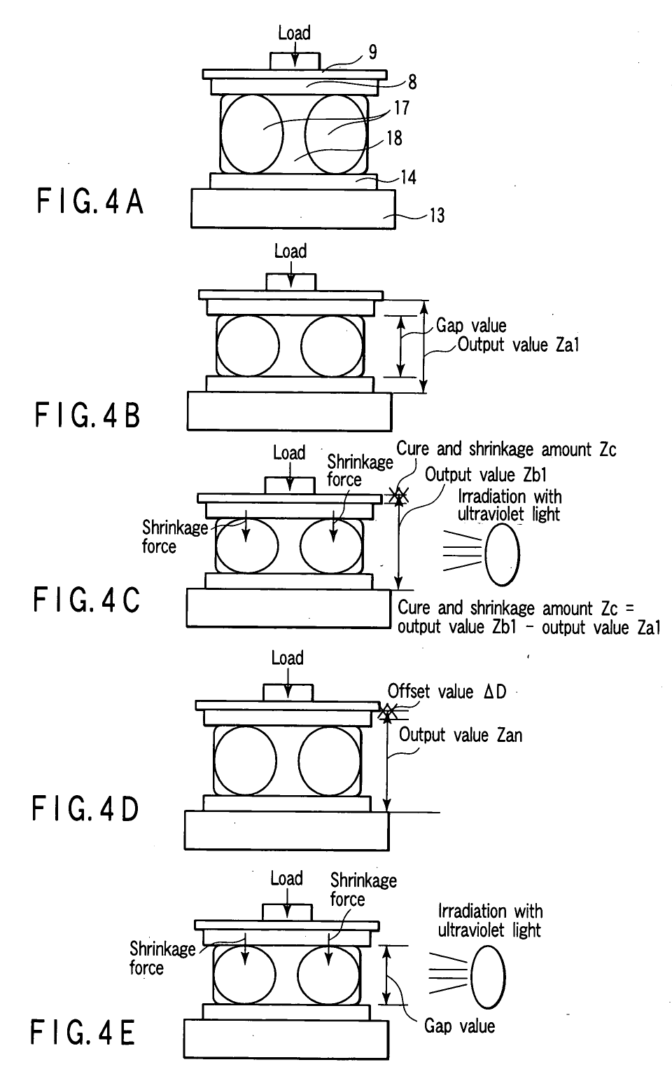

Then, the motor 6 is driven to lower the Z stage 3 (step S4). This brings the semiconductor chip 8 into contact with the spacers. 17 provided on the substrate 14, as shown in FIG. 4A. Subsequently, the motor 6 is driven to lower the Z stage 3 to a predetermined position. At this time, since the pressing mechanism 11 is exerting a predetermined pressing force on the tool 9, the spacer 17 is deformed under the pressing force applied via the tool 9. In this case, there is a correlation between the load imposed by the tool 9 and the deformation amount of the spacers 17. Accordingly, the thrust of the pressing mechanism 11 is controlled so as to generate such a pressing force as results in a desired deformation amount. This makes it possible to control the deformation amount of the spacers 17 to a desired value. However, in this state, when used for junction, the joining material 18 is cured and shrunk to possibly cause the relative distance between the semiconductor chip 8 and the substrate 14 to deviate from the desired value. Thus, according to the first embodiment, control described below is performed so as to offset this deviation.

The spacer 17 is deformed to set the gap between the semiconductor chip 8 and the substrate 14 (referred to as a gap value below) to a desired value. Then, an output value Zal (see FIG. 4B) from the displacement sensor 15 is stored in the memory 19 in the controller 7 (step S5). That is, if the thickness of the semiconductor chip 8 and substrate 14 is known, the gap value obtained after the curing and shrinkage of the joining material 18 can be determined by subtracting the thickness of the semiconductor chip 8 and substrate 14 from the output value Za1. Further, the gap value can be controlled by controlling the deformation amount of the spacers 17. In this case, when the gap value is set to the desired one, the output value from the displacement sensor 15 may be referenced as required to control the pressing force generated by the pressing mechanism 11 so as to obtain the desired gap value.

After the output value Zal has thus been stored in the memory 19, the UV irradiation device 16 is activated to apply ultraviolet rays to the substrate 14 to cure the joining material 18 (step S6). That is, since the stage 13 and the substrate 14 allow ultraviolet rays to pass through, the applied ultraviolet rays reach the joining material 18. Further, since the joining material 18 is of the ultraviolet curing type, the ultraviolet rays subject the joining material 18 to curing reaction. At the same time, the joining material 18 is cured and shrunk, so that the joining material 18 exerts the curing and shrinking force of the joining material 18 on the semiconductor chip 8 as shown in FIG. 4C. This increases the deformation amount of the spacers 17. Correspondingly, the gap value decreases.

The substrate 14 is thus irradiated with ultraviolet rays from the UV irradiation device 16 for a predetermined time. Then, the curing of the joining material 18 is finished, and the current height of the tool 9, that is, an output value Zb1 from the displacement sensor 15, is stored in the memory 19 (step S7). Then, the output values Za1 and Zb1 stored in the memory 19 are used to determine the cure and shrinkage amount of the spacers 17 as a result of the curing and shrinkage of the joining material 18, that is, Zc=Zb1−Za1. The cure and shrinkage amount Zc determined is stored in the memory 19 (step S8). Subsequently, the semiconductor chip 8 is released from being held by the tool 9. The motor 6 is then driven to elevate the Z stage 3 to a predetermined position. Moreover, the part is released from being held by the stage 13. The part is discharged from the present semiconductor joining apparatus (step S9). Thus, the first joining of the semiconductor chip 8 and the substrate 14 is completed.

Subsequently, the process transfers to the joining of the next parts. Specifically, the next substrate 14 and semiconductor chip 8 are held. Then, the relative positions of the substrate 14 and semiconductor chip 8 are adjusted. The pressing mechanism 11 is caused to generate a thrust (step S10). Then, the Z stage 3 is lowered as in the case of the first process. However, for the second and subsequent joining, the tool 9 is positioned so that its height is offset from a desired gap value by ΔD (step S11). In this case, AD=the cure and shrinkage amount Zc calculated in step S8 (see FIG. 4D).

Specifically, the height of the tool 9 is controlled by using the pressing mechanism 11 to exert a pressing force on the spacers 17 to vary the deformation amount of the spacers 17. However, for the second and subsequent joining, the height of the tool 9 is offset by AD with reference to the output from the displacement sensor 15. For example, if AD has a negative value, the pressing force of the pressing mechanism 11 is weakened to reduce the deformation amount of the spacer 17. Accordingly, the tool 9 is located the distance AD above the predetermined position.

Then, as in the case of step S7, the joining material 18 is irradiated with ultraviolet rays from the UV irradiation device 16. The joining material 18 is thus cured (step S12). On this occasion, since the joining material 18 is cured and shrunk, the tool 9 holding the semiconductor chip 8 lowers by a distance corresponding to the cure and shrinkage amount before the irradiation with ultraviolet rays is ended. However, according to the first embodiment, the tool 9 is pre-located the distance above the distance corresponding to the cure and shrinkage amount Zc=ΔD. Consequently, even after the joining material 18 has been completely cured, the desired gap value can be obtained (see FIG. 4E). After the joining material 18 has thus been cured, the part is discharged from the present semiconductor joining apparatus in the same manner as in step S9 (step S13). If the next parts are further to be joined together, the processing in steps S10 to S13 is repeated.

Here, the offset amount ΔD need not necessarily be determined during joining carried out by the present semiconductor joining apparatus. It is possible to use a value determined through experiments using another apparatus. In this case, the cure and shrinkage amount may be calculated using a process similar to that shown in FIG. 2. Another method may be used for the calculation.

Further, in addition to the positioning mechanisms for the directions of the X and Y axes, the stage θ may have positioning mechanisms for a direction α (rotation around a Z axis), and directions a (inclination from the direction from the X axis) and β (inclination from the direction from the Y axis) as required.

Alternatively, the spacers 17 and the joining material 18 may be provided on a surface of the semiconductor chip 8 which is opposite the substrate 14 rather than on the substrate 14. Furthermore, the spacers 17 and the joining material 18 need not be pre-provided on the semiconductor chip 8 or the substrate 14. The spacers 17 and the joining material 18 may be supplied by a supply device (not shown) after being held on the tool 9 or the stage 13.

Moreover, when a heater (not shown) is installed on at least one of the tool 9 and stage 13, a thermosetting adhesive can be used as the joining material 18 in place of the ultraviolet curing adhesive. In this case, the ultraviolet transmission material need not be used for the stage 13 or substrate 14. Further, the UV irradiation apparatus 16 need not be provided.

As described above, according to the first embodiment, by using the displacement sensor 15 to measure the height of the tool 9 holding the semiconductor chip 8, it is possible to measure the amount of change in the height of the tool 9 associated with the curing and shrinkage of the joining member 18. This also enables the measurement of the amount of change in the height of the semiconductor chip 8. Therefore, by storing the cure and shrinkage amount Zc in the memory 19, it is possible to locate the tool 9 at a position offset from the predetermined height by AD determined from the cure and shrinkage amount Zc stored in the memory 19. Thus, even if the height of the semiconductor chip 8 is changed by the curing and shrinkage of the joining material 18, it is possible to perform a joining operation with the gap between the semiconductor chip 8 and the substrate 14 set at the desired value, that is, with the desired gap value.

### Second Embodiment

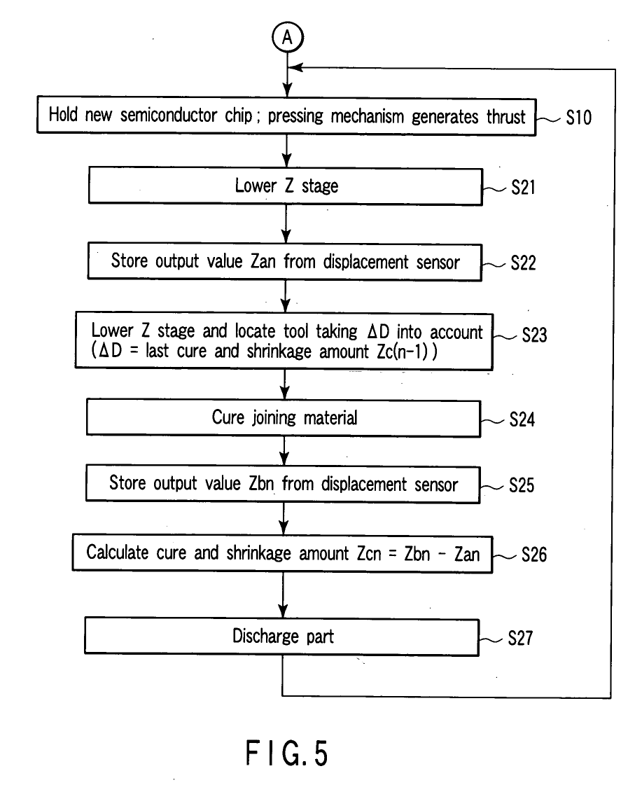

A second embodiment of the present invention will be described. The second embodiment of the present invention is a first variation of the technique for calculating the offset amount ΔD. A configuration according to the second embodiment is similar to that of the first embodiment. Its description is thus omitted using the same reference numerals as those in the first embodiment. Description will be given only of a process executed to join parts together. FIG. 5 is a flowchart showing the process executed to join parts together according to the second embodiment. The process preceding the one shown in FIG. 5, that is, a process for the first joining, is similar to the one shown in FIG. 2. Its description is thus omitted.

For the second and subsequent joining of parts, the new substrate 14 and semiconductor chip 8 are held. Then, the relative positions of the substrate 14 and semiconductor chip 8 are adjusted. The pressing mechanism 11 is caused to generate a thrust (step S10). Then, the Z stage 3 is lowered (step S21). Thus, a load is imposed on the spacers 17 interposed between the semiconductor chip 8 and the substrate 14 to deform the spacers 17. Consequently, the gap between the semiconductor chip 8 and the substrate 14 has the desired value. Then, the current output value Zan (n is a natural number indicating the ordinal of the joining) from the displacement sensor 15 is stored in the memory 19 (step S22).

Then, the thrust of the pressing mechanism 11 is controlled to position the tool 9 so that its height is offset by ΔD (step S23). In this case, ΔD=the cure and shrinkage amount calculated during the last joining, that is, the latest cure and shrinkage amount Zc(n−1) stored in the memory 19. For example, for the second joining, ΔD is the cure and shrinkage amount calculated in step S8. The third and subsequent joining will be described later. After this positioning, the joining material 18 is irradiated with ultraviolet rays from the UV irradiation device 16 for a predetermined time to cure the joining material 18 (step S24). Thus, the joining material 18 is cured and shrunk to deform the spacers 17 by ΔD. This makes it possible to obtain the desired gap value.

After the joining material 18 has thus been completely cured, an output value Zbn from the displacement 15 is stored in the memory 19 (step S25). Then, the cure and shrinkage amount during the current joining Zcn=Zbn−Zan is calculated and stored in the memory 19 (step S26). The cure and shrinkage amount Zcn is utilized in step S23 during the next joining (the third or subsequent joining). Subsequently, the part is discharged from the present semiconductor joining apparatus in the same manner as in the first embodiment (step S27).

As described above, according to the second embodiment, instead of a constant, the cure and shrinkage amount calculated during the last joining is used as the offset amount ΔD. Therefore, the last joining state can always be reflected in the offset amount ΔD. As a result, the gap value can be obtained more accurately than when the technique of the first embodiment is used.

The reliability of Zcn may also be determined when the cure and shrinkage amount Znc is calculated in step S26. Then, only the value determined to be reliable may be utilized for the next joining.

### Third Embodiment

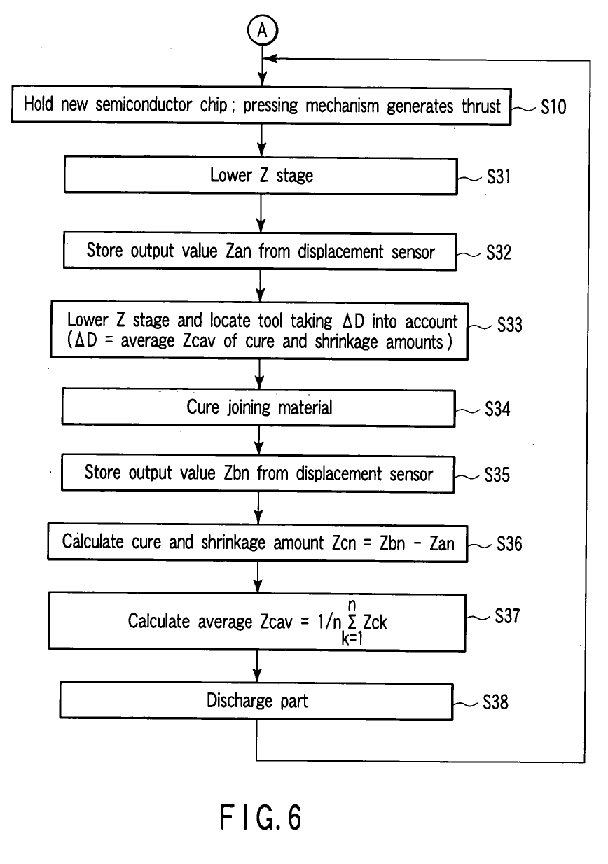

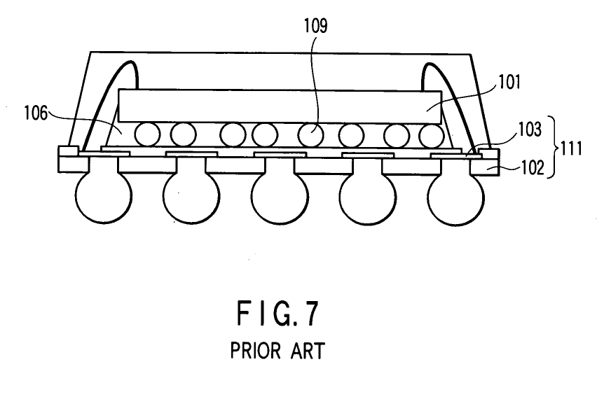

A third embodiment of the present invention will be described. The third embodiment of the present invention is a second variation of the technique for calculating the offset amount ΔD. A configuration according to the third embodiment is similar to that of the first embodiment. Its description is thus omitted using the same reference numerals as those in the first embodiment. Description will be given only of a process executed to join parts together. FIG. 6 is a flowchart showing the process executed to join parts together according to the third embodiment. The process preceding the one shown in FIG. 6, that is, a process for the first joining, is similar to the one shown in FIG. 2. Its description is thus omitted.

For the second and subsequent joining of parts, the new substrate 14 and semiconductor chip 8 are held. Then, the relative positions of the substrate 14 and semiconductor chip 8 are adjusted. The pressing mechanism 11 is caused to generate a thrust (step S10). Then, the Z stage 3 is lowered (step S31). Thus, a load is imposed on the spacers 17 interposed between the semiconductor chip 8 and the substrate 14 to deform the spacers 17. Consequently, the gap between the semiconductor chip 8 and the substrate 14 has the desired value. Then, the current output value Zan from the displacement sensor 15 is stored in the memory 19 (step S32).

Then, the thrust of the pressing mechanism 11 is controlled to position the tool 9 so that its height is offset by ΔD (step S33). In this case, ΔD=the average of the magnitudes of curing and shrinkage. Subsequently, the joining material 18 is irradiated with ultraviolet rays from the UV irradiation device 16 for a predetermined time to cure the joining material 18 (step S34). Thus, the joining material 18 is cured and shrunk to deform the spacers 17 by ΔD. This makes it possible to obtain the desired gap value.

After the joining material 18 has thus been completely cured, the output value Zbn from the displacement 15 is stored in the memory 19 (step S35). Then, the cure and shrinkage amount during the current joining Zcn=Zbn−Zan is calculated (step S36). Subsequently, the average Zcav of the magnitudes of curing and shrinkage is calculated (step S37). The next joining operation is performed taking Zcav into account. Subsequently, the part is discharged from the present semiconductor joining apparatus in the same manner as in the first embodiment (step S38).

As described above, according to the third embodiment, instead of a constant, the average of magnitudes of curing and shrinkage calculated during the past joining operations is used as the offset amount ΔD. That is, in this case, the offset amount ΔD can be calculated taking errors in the cure and shrinkage amount. Consequently, the gap value can be obtained much more accurately than when the technique of the first embodiment is used. Further, since the average of the magnitudes of curing and shrinkage is used, it is possible to absorb differences in the cure and shrinkage amount resulting from a variation in the amount of joining material 18 applied during joining.

In the third embodiment, the average Zcav is calculated over the range from the first to n-th magnitudes of curing and shrinkage. However, actually, the average may be calculated over an arbitrary range. For example, Zcav may be the average of ten values of the cure and shrinkage amount immediately before joining.

Further, according to the third embodiment, when the cure and shrinkage amount Zcav is calculated, its reliability may be determined as described in the second embodiment. It is also possible that values determined to be unreliable are not utilized in calculating the average.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of joining a semiconductor in which a semiconductor chip and a substrate are joined together so that spacers and a joining material are interposed between the semiconductor chip and the substrate, the method comprising controlling a gap between the semiconductor chip and the substrate during joining on the basis of information on curing and shrinkage of the joining material.

2. The method of joining a semiconductor according to claim 1, wherein the information on the curing and shrinkage of the joining material includes information stored in a predetermined storage section.

3. The method of joining a semiconductor according to claim 2, wherein the curing and shrinkage information stored in the storage section relates to the amount of displacement of the gap between the semiconductor chip and the substrate, the displacement being associated with the curing and shrinkage of the joining material.

4. A method of joining a semiconductor, the method comprising:
firstly pressing a semiconductor chip held by a tool against a substrate held on a stage with spacers and a joining material interposed between the semiconductor chip and the substrate;
firstly curing the joining material interposed between the semiconductor chip and the substrate after the firstly pressing;
measuring a displacement amount of the tool when the tool is displaced in a direction of the firstly pressing;
storing the measured displacement amount;
secondly pressing the semiconductor chip against the substrate with a gap between the semiconductor chip and the substrate offset on the basis of the stored displacement amount when the semiconductor chip is pressed against the substrate with the spacers and the joining material interposed between the semiconductor chip and the substrate after each of the firstly pressing, the firstly curing, the measuring, and the storing has been executed at least once; and
secondly curing the joining material interposed between the semiconductor chip and the substrate after the secondly pressing.

5. The method of joining a semiconductor according to claim 4, wherein joining is carried out by repeating the secondly pressing and the secondly curing after a process consisting of the firstly pressing, the firstly curing, the measuring, the storing, the secondly pressing, and the secondly curing has been executed at least once.

6. The method of joining a semiconductor according to claim 5, wherein during the secondly pressing, the gap between the semiconductor chip and the substrate is offset on the basis of an average of a plurality of displacement amounts obtained by executing the measuring and the storing plural times.

7. The method of joining a semiconductor according to claim 4, wherein joining is carried out by repeating the measuring, the storing, the secondly pressing, and the secondly curing after a process consisting of the pressing, the curing, the measuring, the storing, the secondly pressing, and the secondly curing has been executed at least once.

8. The method of joining a semiconductor according to claim 7, wherein during the secondly pressing, the gap between the semiconductor chip and the substrate is offset on the basis of an average of a plurality of displacement amounts obtained by executing the measuring and the storing plural times.

9. The method of joining a semiconductor according to claim 4, wherein during the secondly pressing, the gap between the semiconductor chip and the substrate is offset on the basis of an average of a plurality of displacement amounts obtained by executing the measuring and the storing plural times.

10. A semiconductor joining apparatus which joins a semiconductor chip and a substrate together so that spacers and a joining material are interposed between the semiconductor chip and the substrate, the apparatus comprising a control section which controls a gap between the semiconductor chip and the substrate during joining on the basis of information on curing and shrinkage of the joining material.

11. The semiconductor joining apparatus according to claim 10, further comprising a storage section which stores the information on the curing and shrinkage of the joining material.

12. The semiconductor joining apparatus according to claim 11, wherein the curing and shrinkage information stored in the storage section includes information on the amount of displacement of the gap between the semiconductor chip and the substrate, the displacement being associated with the curing and shrinkage of the joining material.

13. A semiconductor joining apparatus which joins a semiconductor chip and a substrate together so that spacers and a joining material are interposed between the semiconductor chip and the substrate, the apparatus comprising:
a tool which holds the semiconductor chip;
a stage which holds the substrate;
a pressing section which presses the semiconductor chip against the substrate by adjusting a thrust of the tool;
a displacement sensor which measures, when the semiconductor chip is pressed against the substrate, the displacement amount of the tool in a direction of the pressing;
a storage section which stores an output value from the displacement sensor; and
a control section which controls a position of the tool in the direction of the pressing on the basis of the output value stored in the storage section.

14. The semiconductor joining apparatus according to claim 13, wherein the control section uses an offset amount corresponding to the output value from the displacement sensor to control the pressing section so that a gap between the semiconductor chip and the substrate is offset.

15. The semiconductor joining apparatus according to claim 14, wherein the storage section stores a plurality of output values from the displacement sensor.

16. The semiconductor joining apparatus according to claim 15, wherein the control section controls the position of the tool in the direction of the pressing on the basis of a latest one of the plurality of output values stored in the storage section.

17. The semiconductor joining apparatus according to claim 15, wherein the control section controls the position of the tool in the direction of the pressing on the basis of an average of the plurality of output values stored in the storage section.

18. The semiconductor joining apparatus according to claim 13, wherein the storage section stores a plurality of output values from the displacement sensor.

19. The semiconductor joining apparatus according to claim 18, wherein the control section controls the position of the tool in the direction of the pressing on the basis of a latest one of the plurality of output values stored in the storage section.

20. The semiconductor joining apparatus according to claim 18, wherein the control section controls the position of the tool in the direction of the pressing on the basis of an average of the plurality of output values stored in the storage section.
